(19) United States
(12) Patent Application Publication
(10) Pub. No.: US 2026/0284694 A1
(43) Pub. Date: Sep. 24, 2026

(54) SUBSTRATE PROCESSING APPARATUS AND SUBSTRATE PROCESSING METHOD

(71) Applicant: SEMES CO., LTD., Cheonan-si (KR)

(72) Inventors: Yong Jun KIM, Anyang-si (KR); Tae-keun KIM, Siheung-si (KR); Junhee CHOI, Yongin-si (KR); Kang Sul KIM, Hwaseong-si (KR); Kyeong Min LEE, Hwaseong-si (KR)

(21) Appl. No.: 19/566,411

(22) Filed: Mar. 13, 2026

Related U.S. Application Data
(62) Division of application No. 18/502,487, filed on Nov. 6, 2023, now abandoned.

(30) Foreign Application Priority Data
Nov. 24, 2022 (KR) 10-2022-0159225

(51) Int. Cl. B05C 5/00; B05C 13/00; H10P 70/00; H10P 72/00

(52) U.S. Cl. CPC B05C 5/001; B05C 13/00; H10P 70/20; H10P 72/0404

(57) ABSTRACT

A substrate processing method includes loading a substrate by placing the substrate on a substrate supporter in a treatment space within a housing, preheating the substrate by ejecting a heat transfer medium having a first temperature to the substrate while the substrate is stationary, and subsequent to the preheating, and while rotating the substrate supporter to rotate the substrate, supplying a liquid chemical having a second temperature lower than the first temperature toward an upper surface of the substrate supported by the substrate supporter, the liquid chemical being a polymer-based cleaning solution for performing a cleaning process on the substrate.

### CROSS-REFERENCE TO RELATED PATENT APPLICATION

This application is a divisional application of U.S. patent application Ser. No. 18/502,487, filed Nov. 6, 2023, which claims the benefit of Korean Patent Application No. 10-2022-0159225, filed on Nov. 24, 2022, in the Korean Intellectual Property Office, the disclosure of each of which is incorporated herein in its entirety by reference.

### BACKGROUND OF THE DISCLOSURE

### 1. Field of the Disclosure

The present disclosure relates to a substrate processing apparatus and a substrate processing method and, more particularly, to a substrate processing apparatus capable of allowing a liquid chemical to penetrate deeply into patterns provided on a wafer, and a substrate processing method using the same.

### 2. Description of the Related Art

Semiconductor devices are manufactured through a plurality of processes such as diffusion, photolithography, etching, and deposition. In this case, cleaning is performed between processes such as diffusion, etching, and grinding.

Due to recent technological advancement, e.g., finer substrate patterns, as a significant process to increase a semiconductor yield, cleaning is performed to remove impurities on the substrate surface by using a chemical substance, a gas, or a physical method.

Various types of liquid chemicals may be used for the cleaning process, and a liquid chemical may be ejected onto the substrate after a liquid chemical supply device adjusts a concentration and a temperature of the liquid chemical. The liquid chemical is simply ejected from above the center of the substrate, moves outward due to centrifugal force of the rotating substrate, and penetrates between patterns of the substrate.

However, according to the above-described method, when the liquid chemical moves between the patterns of the substrate, a resistance applied to the liquid chemical increases toward the walls of the patterns and a penetration depth of the liquid chemical is limited. Therefore, impurities near the bottoms of the patterns are not easily removed and this problem occurs more seriously when the substrate has a small pattern spacing or includes hole patterns.

### SUMMARY OF THE DISCLOSURE

The present disclosure provides a substrate processing apparatus and substrate processing method capable of preventing damage to a substrate due to physical or chemical processing and of allowing a liquid chemical to penetrate deeply between patterns of the substrate during a cleaning process. However, the above description is an example, and the scope of the present disclosure is not limited thereto.

According to an aspect of the present disclosure, there is provided a substrate processing apparatus including a housing for forming a treatment space where a substrate is processed, a substrate supporter mounted in the treatment space to rotate about a rotational axis, and provided to support the substrate, a liquid chemical supplier provided above the substrate supporter to eject a liquid chemical toward an upper surface of the substrate supported by the substrate supporter, and an ejector provided at a side of the treatment space to eject a heat transfer medium with a temperature different from the temperature of the liquid chemical onto the substrate.

In one implementation of the substrate processing apparatus, the ejector may be provided at an upper portion of the housing to eject the heat transfer medium toward an upper surface of the substrate supported by the substrate supporter.

In one implementation of the substrate processing apparatus, the ejector may be provided on the substrate supporter to eject the heat transfer medium toward a lower surface of the substrate supported by the substrate supporter.

In one implementation of the substrate processing apparatus, the temperature of the heat transfer medium may be relatively higher than the temperature of the liquid chemical.

In one implementation of the substrate processing apparatus, the heat transfer medium may include a gas or a liquid.

In one implementation of the substrate processing apparatus, the gas may include nitrogen gas (N₂) or an inert gas.

In one implementation of the substrate processing apparatus, the liquid may include deionized (DI) water or a solvent component of the liquid chemical.

In one implementation of the substrate processing apparatus, the substrate supporter may include a heater embedded to heat the substrate.

In one implementation of the substrate processing apparatus, the substrate processing apparatus may further include a controller electrically connected to the liquid chemical supplier and the ejector to receive heat transfer medium ejection timing information from the ejector and to apply a control signal to the liquid chemical supplier based on the heat transfer medium ejection timing information so as to control the liquid chemical supplier to eject the liquid chemical.

According to another aspect of the present disclosure, there is provided a substrate processing method using a substrate processing apparatus including a housing for forming a treatment space where a substrate is processed, a substrate supporter mounted in the treatment space to rotate about a rotational axis, and provided to support the substrate, a liquid chemical supplier provided above the substrate supporter to eject a liquid chemical toward an upper surface of the substrate supported by the substrate supporter, and an ejector provided at a side of the treatment space to eject a heat transfer medium with a temperature different from the temperature of the liquid chemical onto the substrate, the substrate processing method including a substrate loading step for loading the substrate into the treatment space of the housing so as to be supported by the substrate supporter, a heat transfer medium ejection step for ejecting the heat transfer medium with the temperature different from the temperature of the liquid chemical onto the substrate, and a liquid chemical ejection step for supplying the liquid chemical toward the upper surface of the substrate.

In one implementation of the substrate processing method, the heat transfer medium ejection step may include a step of ejecting the heat transfer medium toward the upper surface of the substrate supported by the substrate supporter, by using the ejector provided at an upper portion of the housing.

In one implementation of the substrate processing method, the heat transfer medium ejection step may include a step of ejecting the heat transfer medium toward a lower surface of the substrate supported by the substrate supporter, by using the ejector provided on the substrate supporter.

In one implementation of the substrate processing method, the temperature of the heat transfer medium may be relatively higher than the temperature of the liquid chemical.

In one implementation of the substrate processing method, the heat transfer medium may include a gas or a liquid.

In one implementation of the substrate processing method, the gas may include nitrogen gas (N₂) or an inert gas.

In one implementation of the substrate processing method, the liquid may include deionized (DI) water or a solvent component of the liquid chemical.

In one implementation of the substrate processing method, the method may further include a step of preheating the substrate by using a heater embedded in the substrate supporter, before the heat transfer medium ejection step.

In one implementation of the substrate processing method, the heat transfer medium ejection step may include a step of ejecting the heat transfer medium while the substrate is not rotating.

In one implementation of the substrate processing method, the liquid chemical ejection step may include a step of ejecting the liquid chemical while rotating the substrate.

According to another aspect of the present disclosure, there is provided a substrate processing apparatus including a housing for forming a treatment space where a substrate is processed, a substrate supporter mounted in the treatment space to rotate about a rotational axis, and provided to support the substrate, a liquid chemical supplier provided above the substrate supporter to eject a liquid chemical toward an upper surface of the substrate supported by the substrate supporter, and an ejector provided at a side of the treatment space to eject a heat transfer medium with a temperature relatively higher than the temperature of the liquid chemical onto the substrate, wherein the ejector is provided at an upper portion of the housing to eject the heat transfer medium toward an upper surface of the substrate supported by the substrate supporter, or provided on the substrate supporter to eject the heat transfer medium toward a lower surface of the substrate supported by the substrate supporter, wherein the heat transfer medium includes a gas or a liquid, the gas including nitrogen gas (N₂) or an inert gas and the liquid including deionized (DI) water or a solvent component of the liquid chemical, wherein the substrate supporter includes a heater embedded to heat the substrate, and wherein the substrate processing apparatus further includes a controller electrically connected to the liquid chemical supplier and the ejector to receive heat transfer medium ejection timing information from the ejector and to apply a control signal to the liquid chemical supplier based on the heat transfer medium ejection timing information so as to control the liquid chemical supplier to eject the liquid chemical.

### BRIEF DESCRIPTION OF THE DRAWINGS

The above and other features and advantages of the present disclosure will become more apparent by describing in detail embodiments thereof with reference to the attached drawings in which:

FIG. 1 is a plan view of a substrate processing equipment according to an embodiment of the present disclosure;

FIG. 2 is a cross-sectional view of a substrate processing apparatus according to an embodiment of the present disclosure;

FIG. 3 is an enlarged cross-sectional view of an ejector according to an embodiment of the present disclosure;

FIG. 4 is a flowchart of a substrate processing method according to an embodiment of the present disclosure;

FIGS. 5 to 8 are views for describing the substrate processing method of FIG. 4, according to various embodiments of the present disclosure; and

FIGS. 9 to 12 are views for describing an existing substrate cleaning method.

### DETAILED DESCRIPTION OF THE DISCLOSURE

Hereinafter, the present disclosure will be described in detail by explaining embodiments of the disclosure with reference to the attached drawings.

The disclosure may, however, be embodied in many different forms and should not be construed as being limited to the embodiments set forth herein; rather, these embodiments are provided so that this disclosure will be thorough and complete, and will fully convey the concept of the disclosure to one of ordinary skill in the art. In the drawings, the thicknesses or sizes of layers are exaggerated for clarity and convenience of explanation.

Embodiments of the disclosure are described herein with reference to schematic illustrations of idealized embodiments (and intermediate structures) of the disclosure. As such, variations from the shapes of the illustrations as a result, for example, of manufacturing techniques and/or tolerances, are to be expected. Thus, the embodiments of the disclosure should not be construed as limited to the particular shapes of regions illustrated herein, but are to include deviations in shapes that result, for example, from manufacturing.

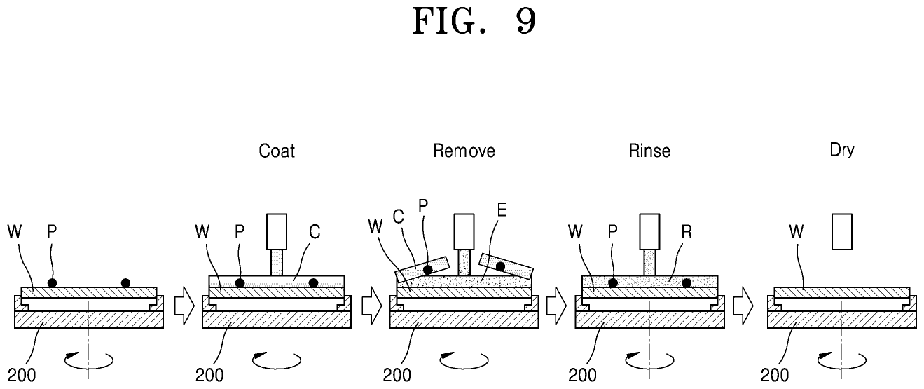

FIGS. 9 to 12 are views for describing an existing substrate cleaning method.

Initially, referring to FIG. 9, an existing substrate cleaning apparatus removes particles by using physical force or using chemical reaction of a liquid chemical. However, according to the above-described methods, patterns T on the surface of a substrate W may be damaged by physical force, or an underlayer of the substrate W may be eroded by etching or the like.

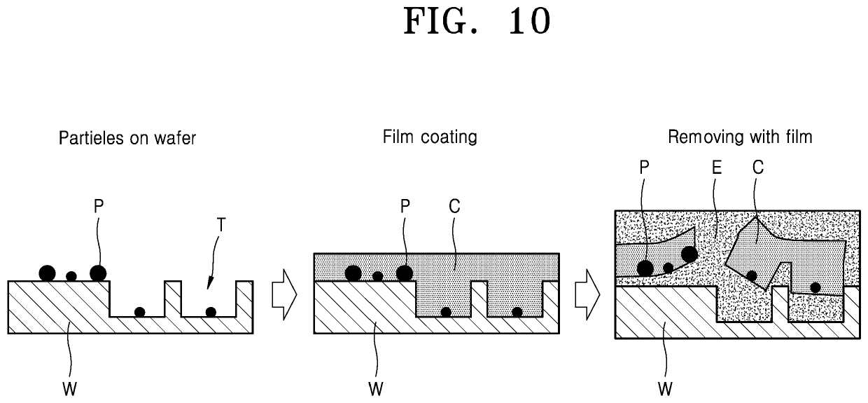

Specifically, referring to FIG. 10, the substrate W is disposed on a chuck 200 (See FIG. 9), and a liquid chemical C is ejected onto the substrate W with particles P (Particles on wafer in FIG. 10). The liquid chemical C includes a volatile component and may use a treatment liquid for deposition to deposit a topcoat film on the substrate W. The treatment liquid is coated as a protective layer on an upper surface of a resist layer to prevent penetration of an immersion liquid into the resist layer. The immersion liquid is, for example, a liquid used for immersion lithography in a lithography process. However, the type of the liquid chemical C is not limited to the above example.

The liquid chemical C is simply ejected from above the center of the substrate W and moves outward due to centrifugal force caused by the rotation of the substrate W so as to be filled in the patterns T provided on the substrate W (Coat in FIG. 9) (Film coating in FIG. 10). In this case, because the centrifugal force increases toward the edge of the substrate W at the same rotation speed of the substrate W, the liquid chemical C is pulled to the edge. In addition, due to the increased centrifugal force, the liquid chemical C physically escapes without sufficiently filling the patterns T.

Referring back to FIG. 9, an etchant E is ejected from above the center of the substrate W coated with the liquid chemical C, to remove the liquid chemical C adhered by chemical reaction from the substrate W (Remove in FIG. 9) (Removing with film in FIG. 10). Thereafter, a rinsing solution R is ejected from above the center of the substrate W to rinse the substrate W (Rinse in FIG. 9), and a drying process is performed (Dry in FIG. 9) to transfer the substrate W without the particles P to a subsequent process. The substrate W may be continuously rotated during the above-described cleaning process.

Meanwhile, cleaning efficiency greatly depends on a filling rate of the liquid chemical C between the patterns T. That is, the higher the filling rate of the liquid chemical C, the higher the cleaning efficiency. However, according to the existing method, the filling rate inevitably decreases toward the edge of the substrate W due to the above-described physical phenomenon. This phenomenon may cause uneven cleaning of the substrate W and lead to a major problem in semiconductor yield.

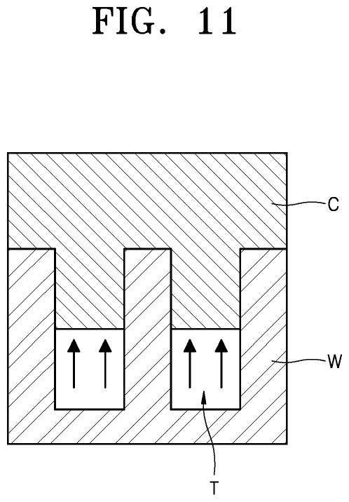

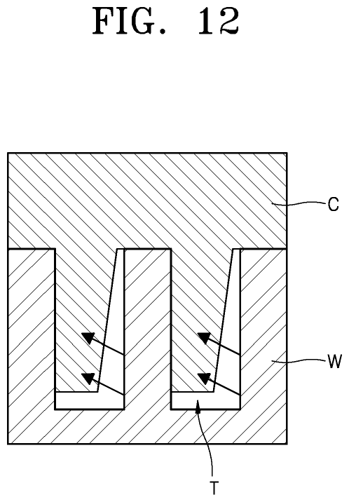

The filling rate of the liquid chemical C is affected by a rotation speed of the substrate W and, when the rotation speed is controlled to be lower than a certain speed, as shown in FIG. 11, the liquid chemical C shrinks along a shrinkage direction and lower regions of the patterns T are not filled. On the other hand, when the rotation speed of the substrate W is controlled to be higher than the certain speed, as shown in FIG. 12, the shrinkage direction may be tilted along an arrow direction and the liquid chemical C may be diagonally filled to the lower regions of the patterns T. In this case, although a penetration rate of over about 90% is achieved, the shrinkage direction of a film formed by the liquid chemical C may be tilted to a side and thus the particles P in empty spaces may not be easily removed.

To solve the above problem, the present disclosure provides a substrate processing apparatus and substrate processing method capable of removing particles deep inside patterns by initially ejecting a heat transfer medium with a temperature relatively higher than the temperature of a liquid chemical onto a substrate before the liquid chemical is coated on the substrate, and then ejecting the liquid chemical onto the substrate, thereby minimizing pattern damage due to physical or chemical substrate processing and reducing the difference in filling rate between the center and the edge of a substrate.

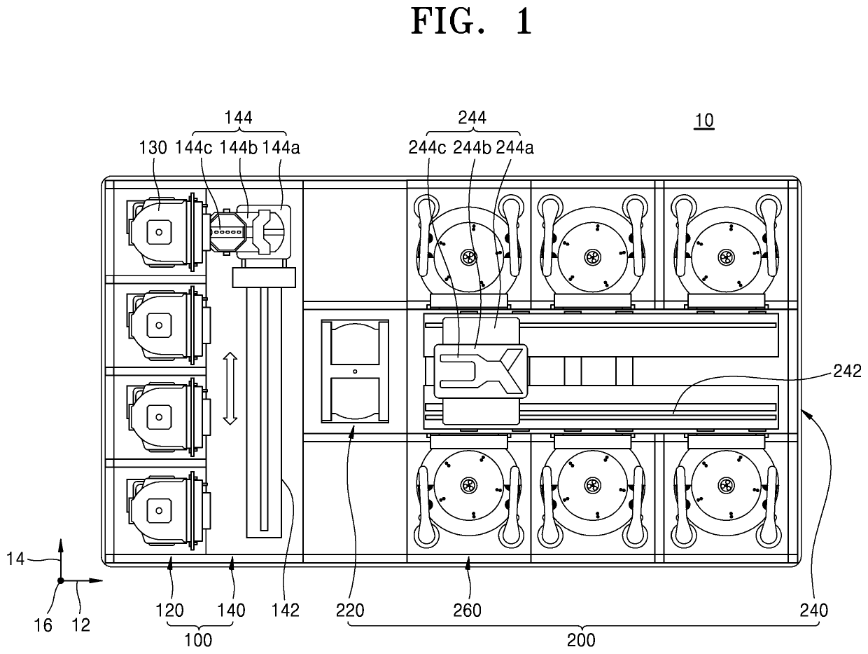

FIG. 1 is a plan view of a substrate processing equipment 10 according to an embodiment of the present disclosure.

Referring to FIG. 1, the substrate processing equipment 10 includes an index module 100 and a process module 200. The index module 100 includes load ports 120 and a transfer frame 140. The load ports 120, the transfer frame 140, and the process module 200 may be sequentially arranged. Herein, a direction in which the load ports 120, the transfer frame 140, and the process module 200 are arranged is referred to as a first direction 12 (or an x-axis direction), a direction perpendicular to the first direction 12 when viewed from above is referred to as a second direction 14 (or a y-axis direction), and a direction perpendicular to a plane including the first and second directions 12 and 14 (i.e., an xy plane) is referred to as a third direction 16 (or a z-axis direction).

Carriers 130 storing substrates W are seated on the load ports 120. A plurality of load ports 120 may be disposed along the second direction 14. The number of load ports 120 may increase or decrease depending on process efficiency of the process module 200, production efficiency, or the like. Each carrier 130 may use a front opening unified pod (FOUP) and include slots for storing a plurality of substrates W horizontally.

The process module 200 includes a buffer unit 220, a transfer housing 240, and process housings 260. The transfer housing 240 may extend parallel to the first direction 12, and the process housings 260 may be disposed at both sides of the transfer housing 240 along a longitudinal direction. Some of the process housings 260 may be stacked on one another. Meanwhile, the process housings 260 may be disposed only at one side of the transfer housing 240.

The buffer unit 220 is disposed between the transfer frame 140 and the transfer housing 240 to provide a space where the substrates W stay before being transferred between the transfer frame 140 and the transfer housing 240. The buffer unit 220 includes slots where the substrates W are disposed. The buffer unit 220 may be provided to be open or openable to the transfer frame 140 and the transfer housing 240.

The transfer frame 140 may transfer the substrates W between the carriers 130 and the buffer unit 220. The transfer frame 140 is provided with an index rail 142 and an index robot 144. The index rail 142 may extend parallel to the second direction 14, and the index robot 144 may be mounted thereon to move along the second direction 14. The index robot 144 includes a base 144a, a body 144b, and index arms 144c. The base 144a is mounted to be movable along the index rail 142. The body 144b is coupled to the base 144a and mounted to be rotatable and movable along the third direction 16 on the base 144a. The index arms 144c are coupled to the body 144b and provided to be movable toward or away from the body 144b. A plurality of index arms 144c may be provided and individually driven. Each index arm 144c may be used to transfer the substrate W from the carrier 130 to the process module 200, or from the process module 200 to the carrier 130.

The transfer housing 240 transfers the substrates W between the buffer unit 220 and the process housings 260 or between the process housings 260. The transfer housing 240 is provided with guide rails 242 and a main robot 244. The guide rails 242 may extend parallel to the first direction 12, and the main robot 244 may be mounted thereon to move along the first direction 12. The main robot 244 includes a base 244a, a body 244b, and main arms 244c. The base 244a is mounted to be movable along the guide rails 242. The body 244b is coupled to the base 244a and mounted to be rotatable and movable along the third direction 16 on the base 244a. The main arms 244c are coupled to the body 244b and provided to be movable toward or away from the body 244b. A plurality of main arms 244c may be provided and individually driven.

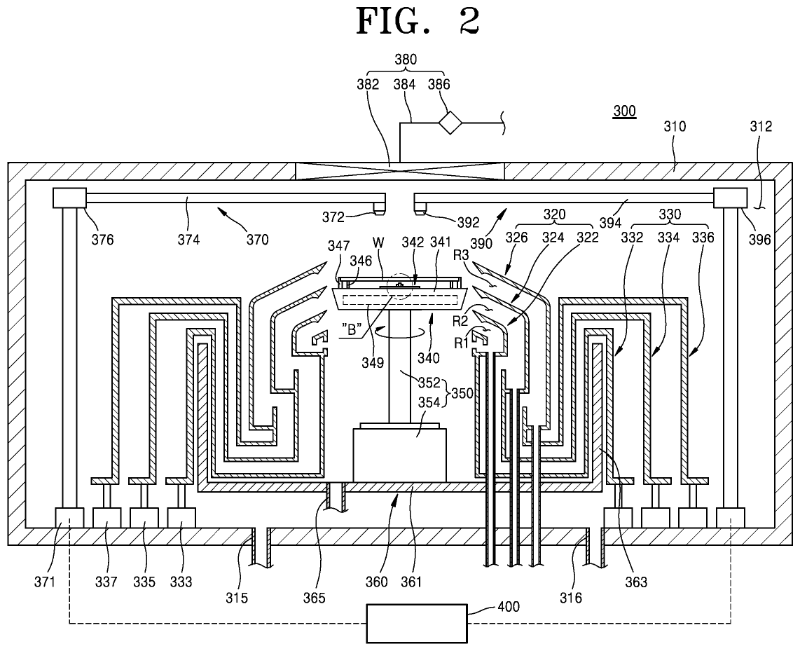

Each process housing 260 is provided with a substrate processing apparatus 300 (see FIG. 2) for performing a process on the substrate W. The substrate processing apparatus 300 may have a different structure depending on the performed process. Meanwhile, the substrate processing apparatuses 300 in all process housings 260 may have the same structure, or the substrate processing apparatuses 300 in the process housings 260 belonging to the same group may have the same structure.

The substrate processing apparatus 300 (see FIG. 2) may perform a heating process for heating the substrate W, and a cooling process for cooling the substrate W. In addition, the substrate processing apparatus 300 (see FIG. 2) may perform a cleaning process for processing the substrate W with a liquid. Although a coating apparatus or a cleaning apparatus is described herein as an example of the substrate processing apparatus 300, the substrate processing apparatus 300 is not limited thereto and is also applicable to a heating apparatus, an etching apparatus, a photolithography apparatus, or the like.

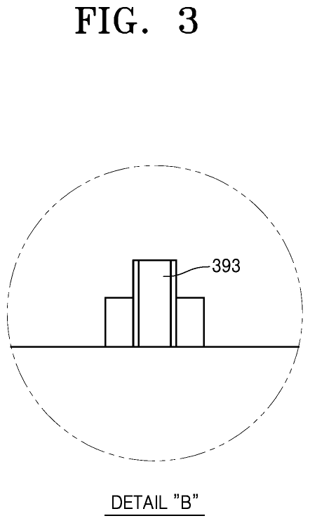

FIG. 2 is a cross-sectional view of a substrate processing apparatus 300 according to an embodiment of the present disclosure. FIG. 3 is an enlarged cross-sectional view of an ejector 390 according to an embodiment of the present disclosure.

The substrate processing apparatus 300 may be used as a coating apparatus for coating a photoresist on the substrate W, or a cleaning apparatus for cleaning the substrate W.

Referring to FIG. 2, the substrate processing apparatus 300 includes a housing 310, a processing vessel 320, a lift 330, a substrate supporter 340, a support driver 350, a base 360, a liquid chemical supplier 370, an airflow supplier 380, and an ejector 390.

The housing 310 provides an internal space. An opening (not shown) may be provided at a side of the housing 310 and used as a passage for the substrate W. A door (not shown) may be mounted on the opening to open or close the opening. When the substrate W is processed, the opening is closed to seal the internal space of the housing 310. Exhaust ports 315 and 316 may be provided at a side of the housing 310 to expel an airflow formed in the housing 310 to the outside.

The processing vessel 320 provides a space where the substrate W is processed. The processing vessel 320 has an open top. The processing vessel 320 includes a plurality of collection barrels 322, 324, and 326. Although three, e.g., first, second, and third, collection barrels 322, 324, and 326 are assumed in an embodiment of the present disclosure, the number of collection barrels may increase or decrease. The collection barrels 322, 324, and 326 are provided to be spaced apart from each other along a vertical direction (or the third direction 16). The collection barrels 322, 324, and 326 may be vertically stacked on one another. The first, second, and third collection barrels 322, 324, and 326 may collect different treatment liquids used in the process. The processing vessel 320 provides one or more reception spaces R1, R2, and R3 formed in a vertical direction (or the third direction 16) to receive the treatment liquids after the substrate W is processed.

The first collection barrel 322 may be disposed to surround the substrate supporter 340, the second collection barrel 324 may be disposed to surround the first collection barrel 322, and the third collection barrel 326 may be disposed to surround the second collection barrel 324. The collection barrels 322, 324, and 326 are provided in a circular ring shape. A space R1 inside the first collection barrel 322, a space R2 between the first and second collection barrels 322 and 324, and a space R3 between the second and third collection barrels 324 and 326 function as the reception spaces R1, R2, and R3 into which the treatment liquids flow. Collection pipes may extend downward from bottom surfaces of the collection barrels 322, 324, and 326 to discharge the treatment liquids introduced into the reception spaces R1, R2, and R3, respectively. The discharged treatment liquids may be reused through an external treatment liquid recycling system (not shown).

The lift 330 is coupled to the collection barrels 322, 324, and 326 to lift the collection barrels 322, 324, and 326. A first lift 332 is connected to the first collection barrel 322, a second lift 334 is connected to the second collection barrel 324, and a third lift 336 is connected to the third collection barrel 326. The lifts 332, 334, and 336 may be connected to driving units 333, 335, and 337, respectively, to receive driving force for vertical motion. The lift 330 may control heights of the collection barrels 322, 324, and 326 to adjust sizes, heights, positions, or the like of the reception spaces R1, R2, and R3.

The substrate supporter 340 supports and rotates the substrate W in an internal space 312 of the housing 310. The internal space 312 may be understood as a treatment space where the substrate W is processed. The substrate supporter 340 includes a rotating support plate 341 and a fixed support plate 342.

The rotating support plate 341 has a substantially circular upper edge when viewed from above. The rotating support plate 341 is positioned outside the fixed support plate 342. The rotating support plate 341 is rotated by the support driver 350. Support pins 346 and chuck pins 347 are provided on the rotating support plate 341. The fixed support plate 342 has a substantially circular upper edge when viewed from above. The fixed support plate 342 is positioned at the center of the substrate supporter 340.

The support driver 350 may rotate or lift the substrate supporter 340. The support driver 350 is connected to the rotating support plate 341 of the substrate supporter 340. The support driver 350 includes a driving shaft 352 and a driving device 354. The driving shaft 352 is rotated by the driving device 354 to rotate the rotating support plate 341. In addition, the driving shaft 352 may be moved or stretched in a vertical direction by the driving device 354 to adjust a height of the substrate supporter 340.

The base 360 is provided in a cylindrical shape surrounding the processing vessel 320 and having an open top. The base 360 includes a bottom 361 and a wall 363. The base 360 is provided in a cup shape. The bottom 361 may be provided in a disk shape and connected to an exhaust pipe 365. The wall 363 extends in a vertical direction from the edge of the bottom 361. The base 360 may be made of a resin material having a high acid resistance. The base 360 substantially functions as an outer wall of the entirety of the processing vessel 320.

The liquid chemical supplier 370 (or a front-side liquid chemical supplier 370) supplies a treatment liquid to the substrate W to process the substrate W. The liquid chemical supplier 370 supplies the treatment liquid to a front side of the substrate W. The liquid chemical supplier 370 includes a nozzle 372 and a pipe 374 which may supply the treatment liquid, and an end of the liquid chemical supplier 370 is connected to a liquid chemical supply device (not shown). A bubble removal pipe 376 is connected to a portion of the pipe 374 to remove bubbles remaining in the treatment liquid.

For example, a treatment liquid such as a photoresist may be ejected from the nozzle 372 of the liquid chemical supplier 370 and coated on the front side of the substrate W. As another example, a liquid chemical or an organic solvent such as isopropyl alcohol (IPA) may be ejected from the nozzle 372 of the liquid chemical supplier 370 to clean or dry the front side of the substrate W.

The airflow supplier 380 forms a downward airflow into the internal space of the housing 310. The airflow supplier 380 includes a fan 382, an airflow supply line 384, and a filter 386. The fan 382 is mounted on top of the housing 310 to form a downward airflow into the internal space of the housing 310. The airflow supply line 384 supplies external air into the housing 310. The filter 386 filters out impurities included in the air.

The exhaust ports 315 and 316 are connected to a gas exhaust device (not shown). Each of the exhaust ports 315 and 316 is connected to a main exhaust line (not shown) of the gas exhaust device (not shown). The exhaust ports 315 and 316 of a plurality of substrate processing apparatuses 300 may be connected to the main exhaust line (not shown) of the gas exhaust device (not shown). Although two exhaust ports 315 and 316 are illustrated in FIG. 3, the number of exhaust ports may increase or decrease depending on the type of the liquid chemical, the type of process by-products, or the like, and each exhaust port may be connected to the main exhaust line (not shown) of the gas exhaust device (not shown).

The ejector 390 supplies a heat transfer medium onto the substrate W when the substrate W is processed. The ejector 390 supplies the heat transfer medium to the front side of the substrate W. The ejector 390 includes a nozzle 392 and a pipe 394 which may supply the heat transfer medium, and an end of the ejector 390 is connected to a heat transfer medium supply device (not shown). For example, the heat transfer medium may be ejected from the nozzle 392 of the ejector 390 onto the front side of the substrate W. The heat transfer medium heated by the heat transfer medium supply device (not shown) and maintained at a higher temperature than the temperature of the liquid chemical may be ejected onto the substrate W through the ejector 390. Herein, a heat transfer medium heater 396 may be further provided to constantly maintain the temperature of the heat transfer medium moving along the pipe 394.

As another example, referring to FIGS. 2 and 3, an ejector 393 may be provided on the substrate supporter 340. The ejector 393 provided on the substrate supporter 340 may eject the heat transfer medium toward a lower surface of the substrate W supported by the substrate supporter 340. In this case, the heat transfer medium may be simultaneously ejected toward the upper surface of the substrate W through the ejector 390 provided at an upper portion of the housing 310.

As another example, the substrate supporter 340 may be provided with a heater 349 to preheat the substrate W before the heat transfer medium is ejected onto the substrate W. Alternatively, a high-temperature atmosphere of patterns on the substrate W may be rapidly controlled by heating the substrate W. In addition, a liquid component included in the liquid chemical may be rapidly volatilized by ejecting the liquid chemical while continuously heating the substrate W onto which the heat transfer medium is ejected.

The substrate processing apparatus 300 may further include a controller 400.

The controller 400 may be electrically connected to the liquid chemical supplier 370 and the ejector 390 to receive heat transfer medium ejection timing information from the ejector 390 and to apply a control signal to the liquid chemical supplier 370 based on the heat transfer medium ejection timing information so as to control the liquid chemical supplier 370 to eject the liquid chemical.

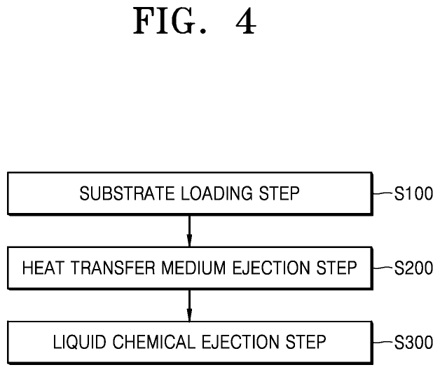

A substrate processing method using the above-described substrate processing apparatus 300 will now be described in detail with reference to FIGS. 4 to 8.

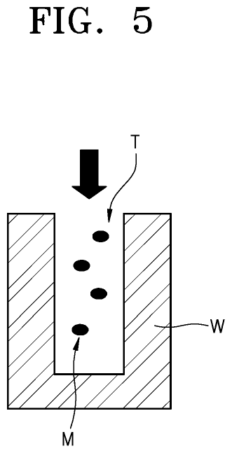

FIG. 4 is a flowchart of a substrate processing method according to an embodiment of the present disclosure. FIGS. 5 to 8 are views for describing the substrate processing method of FIG. 4, according to various embodiments of the present disclosure.

Initially, referring to FIG. 4, the substrate processing method according to an embodiment of the present disclosure includes a substrate loading step S100, a heat transfer medium ejection step S200, and a liquid chemical ejection step S300. The substrate processing method may use the above-described substrate processing apparatus 300 and include the substrate loading step S100 for loading the substrate W into the treatment space 312 of the housing 310 so as to be supported by the substrate supporter 340.

The substrate loading step S100 may include a substrate moving step for moving the substrate W by using a moving unit so as to be accommodated in the housing 310. For example, the moving unit may be provided to move in a vertical direction, a horizontal direction, or all directions.

In general, when the substrate W is cleaned using a liquid chemical C based on a polymer solution, the liquid chemical C may not sufficiently penetrate into the fine patterns T provided on the substrate W.

In this regard, according to the present disclosure, after the substrate W is loaded into the housing 310, the heat transfer medium ejection step S200 for ejecting a heat transfer medium M with a temperature different from the temperature of the liquid chemical C onto any one surface of the substrate W may be performed.

For example, the heat transfer medium M may be ejected onto an upper surface of the substrate W. Specifically, referring to FIGS. 2 and 5, while the substrate W is not rotating (i.e., while the substrate W is in a stationary state), the ejector 390 provided at an upper portion of the housing 310 may directly eject the heat transfer medium M toward the upper surface of the substrate W supported by the substrate supporter 340. In this case, the heat transfer medium M may be filled in the patterns T on the substrate W to form a high-temperature atmosphere similar to the temperature of the heat transfer medium M in the entire vicinity of the substrate W.

The heat transfer medium M may include a gas or a liquid. The gas may include nitrogen gas (N₂) or an inert gas, and the liquid may include deionized (DI) water or a solvent component of the liquid chemical C. For example, the temperature of the heat transfer medium M may be about 70° C. to about 120° C., specifically, about 75° C. to about 100° C., and more specifically, about 80° C. to about 90° C. The heat transfer medium M may be ejected in the form of a spray or ejected in various ways depending on the shape of the nozzle 392.

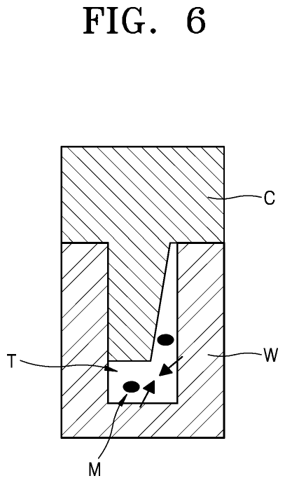

As shown in FIG. 5, the heat transfer medium M with a relatively higher temperature than the temperature of the liquid chemical C may be directly ejected onto the substrate W to increase the temperatures of the substrate W and a gas around the substrate W. Thereafter, as shown in FIG. 6, the liquid chemical ejection step S300 for supplying the liquid chemical C toward the upper surface of the substrate W may be performed.

The liquid chemical ejection step S300 may include a liquid chemical supply step for supplying the liquid chemical C through a pump from a liquid chemical source 371, and a liquid chemical moving step for moving the supplied liquid chemical C through the pipe 374 to the nozzle 372. For example, the liquid chemical supply step may include a liquid chemical adjustment step for adjusting an amount of the liquid chemical C before being supplied from the liquid chemical source 371. By coating the liquid chemical C with a relatively lower temperature than the temperature of the heat transfer medium M on the substrate W, a reduction in volume of the heat transfer medium M may be induced.

When the liquid chemical C is coated, the substrate W may be rotated at 1300 rpm or more (more specifically, at 1500 rpm or more) by the substrate supporter 340. In this case, the rotation of the substrate W may start simultaneously with the coating of the liquid chemical C because, when the substrate W which is increased in temperature is rotated before the liquid chemical Cis coated, the temperature may be lowered by the rotational force of the substrate W. Therefore, after the substrate W is increased to a target temperature by ejecting the heat transfer medium M, the substrate W needs to be rotated at the same time as the liquid chemical C is coated on the substrate W.

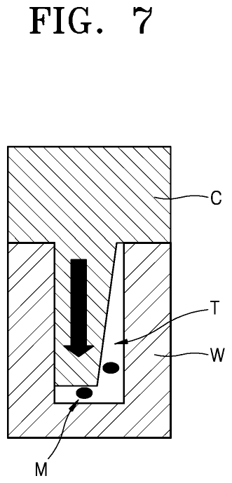

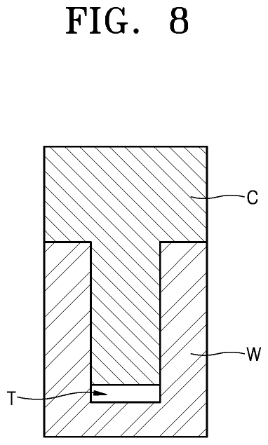

Due to the temperature difference between the substrate W heated to a high temperature and the liquid chemical C with the same temperature as room temperature, a change in volume may be induced by the temperature difference inside the patterns T and thus the liquid chemical C may diagonally penetrate into lower regions of the patterns T along an arrow direction as shown in FIG. 7, and the liquid chemical C may be fully filled deeply into the lower regions of the patterns T as shown in FIG. 8.

As another example, before the heat transfer medium Mis ejected, the substrate W may be preheated using the heater 349 embedded in the substrate supporter 340. Alternatively, the substrate W may be continuously heated using the heater 349 until the ejecting of the heat transfer medium M is terminated.

When a solvent component included in the polymer-based liquid chemical C is vaporized to a high temperature and ejected as the heat transfer medium M, a reduction in volume may occur due to a change in temperature inside the patterns T and the solvent itself may be liquefied and combined with the coated liquid chemical C to increase a penetration rate of the liquid chemical C. In addition, when a high-temperature gas including moisture is ejected as the heat transfer medium M, the inside of the patterns T may not dry out to prevent the retreat of the polymer-based liquid chemical C.

As another example, when the substrate W includes the patterns T which is vulnerable to thermal deformation, the heat transfer medium M with a relatively higher temperature than the temperature of the liquid chemical C may be ejected from below the substrate W to indirectly induce the patterns T to a high-temperature atmosphere. In this case, the ejector 393 provided on the substrate supporter 340 may eject the heat transfer medium M toward a lower surface of the substrate W supported by the substrate supporter 340. Alternatively, to induce a greater change in volume based on a change in temperature inside the patterns T, the heat transfer medium M may be simultaneously ejected toward the upper and lower surfaces of the substrate W.

Therefore, based on the substrate processing apparatus 300 according to the present disclosure, a high-temperature atmosphere of 70° C. or higher may be formed by using the heated nitrogen gas (N₂) gas itself or by heating the surface of the substrate W with the heated nitrogen gas (N₂) gas while the substrate W is not rotating, and then the liquid chemical C such as poly aluminum chloride (PAC) with a relatively lower temperature (e.g., 21° C. to 25° C.) may be supplied to increase a penetration rate of the liquid chemical C by using a change in volume of the nitrogen gas (N₂) between the patterns T and the PAC film.

When the substrate W includes the patterns T which are sensitive to thermal shock, instead of directly applying a high-temperature gas to the substrate W, a high-temperature liquid or gas may be ejected from below the substrate W to form a high-temperature atmosphere around the patterns T by indirectly using the heat from below the substrate W, thereby preventing damage to the patterns T of the substrate W.

According to the afore-described embodiments of the present disclosure, a liquid chemical may penetrate deeply between patterns provided on a substrate without damaging the patterns by using a change in volume of a gas due to a temperature difference inside the patterns by supply a high-temperature gas or liquid onto an upper surface of the substrate. As such, a substrate processing apparatus and substrate processing method capable of efficiently removing impurities near the bottoms of the patterns may be implemented.

In addition, the processing efficiency and the quality of the substrate may be increased by efficiently cleaning the substrate. As such, cost and time wastes caused by detective patterns of the substrate may be reduced. However, the scope of the present disclosure is not limited to the above effects.

While the present disclosure has been particularly shown and described with reference to embodiments thereof, it will be understood by one of ordinary skill in the art that various changes in form and details may be made therein without departing from the scope of the present disclosure as defined by the following claims.

1-20. (canceled)

21. A substrate processing method comprising:
loading a substrate by placing the substrate on a substrate supporter in a treatment space within a housing;
preheating the substrate by ejecting a heat transfer medium having a first temperature to the substrate while the substrate is stationary; and
subsequent to the preheating, and while rotating the substrate supporter to rotate the substrate, supplying a liquid chemical having a second temperature lower than the first temperature toward an upper surface of the substrate supported by the substrate supporter, the liquid chemical being a polymer-based cleaning solution for performing a cleaning process on the substrate.

22. The substrate processing method of claim 21, wherein the rotating of the substrate does not start before the supplying the liquid chemical begins.

23. The substrate processing method of claim 22, wherein the rotating of the substrate and the supplying of the liquid chemical begin simultaneously.

24. The substrate processing method of claim 22, wherein the liquid chemical begins to be supplied to the preheated substrate without the temperature of the preheated substrate being lowered.

25. The substrate processing method of claim 21, wherein an ejector is provided at an upper portion of the housing to eject the heat transfer medium toward an upper surface of the substrate placed on the substrate supporter.

26. The substrate processing method of claim 21, wherein the heat transfer medium comprises a gas or a liquid.

27. The substrate processing method of claim 26, wherein the heat transfer medium comprises an inert gas.

28. The substrate processing method of claim 26, wherein heat transfer medium comprises a liquid, and the liquid comprises deionized water or a solvent component of the liquid chemical.

29. The substrate processing method of claim 21, wherein the heat transfer medium is applied to a top surface of the substrate to fill in patterns in the substrate.

30. The substrate processing method of claim 21, further comprising, subsequent to supplying the liquid chemical, sequentially performing a rinsing process and a drying process on the substrate.

31. A substrate processing method using a substrate processing apparatus comprising a housing for forming a treatment space where a substrate is processed, a substrate supporter mounted in the treatment space to rotate about a rotational axis, and provided to support the substrate, a liquid chemical supplier provided above the substrate supporter to supply a liquid chemical toward an upper surface of the substrate supported by the substrate supporter, and an ejector provided to eject a heat transfer medium having a temperature relatively higher than the temperature of the liquid chemical onto the substrate,
the substrate processing method comprising:
loading the substrate into the treatment space of the housing and placing the substrate on the substrate supporter;
ejecting the heat transfer medium having the temperature higher than the temperature of the liquid chemical onto the substrate to preheat the substrate; and
after the ejecting of the heat transfer medium has stopped, beginning to supply the liquid chemical toward the upper surface of the preheated substrate, the liquid chemical including a polymer-based cleaning solution.

32. The substrate processing method of claim 31, wherein ejecting the heat transfer medium comprises ejecting the heat transfer medium toward the upper surface of the substrate supported by the substrate supporter, by using the ejector, which is provided in an upper portion of the housing.

33. The substrate processing method of claim 31, wherein ejecting the heat transfer medium comprises ejecting the heat transfer medium toward a lower surface of the substrate supported by the substrate supporter, by using the ejector, which is provided on the substrate supporter.

34. The substrate processing method of claim 31, wherein the heat transfer medium comprises a gas or a liquid.

35. The substrate processing method of claim 34, wherein the heat transfer medium comprises an inert gas.

36. The substrate processing method of claim 34, wherein the heat transfer medium comprises a liquid and the liquid comprises deionized (DI) water or a solvent component of the liquid chemical.

37. The substrate processing method of claim 31, further comprising additionally preheating the substrate by using a heater embedded in the substrate supporter, before ejecting the heat transfer medium.

38. The substrate processing method of claim 31, wherein ejecting the heat transfer medium comprises ejecting the heat transfer medium while the substrate is not rotating.

39. The substrate processing method of claim 38, wherein supplying the liquid chemical comprises ejecting the liquid chemical while rotating the substrate.

40. A substrate processing method comprising:
loading a substrate by placing the substrate on a substrate supporter in a treatment space within a housing;
preheating the substrate by ejecting a heat transfer medium having a first temperature to the substrate;
subsequent to the preheating, and while the substrate is at the preheated temperature, rotating the substrate, supplying a liquid chemical having a second temperature lower than the first temperature toward an upper surface of the substrate supported by the substrate supporter, the liquid chemical being a cleaning solution for performing a cleaning process on the substrate; and
subsequent to supplying the liquid chemical, sequentially performing a rinsing and a drying process on the substrate.
